(19) United States
(12) Patent Application Publication
(10) Pub. No.: US 2016/0027941 A1
(43) Pub. Date: Jan. 28, 2016

(54) MULTILAYER FILM, BACK SHEET FOR SOLAR CELL MODULE, AND SOLAR CELL MODULE

(71) Applicant: FUJIFILM Corporation, TOKYO (JP)

(72) Inventors: NAOMI WATANABE, SHIZUOKA (JP); RYUTA TAKEGAMI, SHIZUOKA (JP); SHIN OZAWA, SHIZUOKA (JP)

(73) Assignee: FUJIFILM Corporation, Tokyo (JP)

(21) Appl. No.: 14/872,163

(22) Filed: Oct. 1, 2015

Related U.S. Application Data
(63) Continuation of application No. PCT/JP2014/057530, filed on Mar. 19, 2014.

(30) Foreign Application Priority Data
Apr. 2, 2013 (JP) 2013-076755

(51) Int. Cl. H01L 31/049; H01L 31/048

(52) U.S. Cl. CPC H01L 31/049; H01L 31/0481

(57) ABSTRACT

Disclosed is a multilayer film including a polyester support body; a first adhesive layer laminated on at least one surface of the polyester support body; and a second adhesive layer laminated on a side opposite to the polyester support body through the first adhesive layer, in which an average film thickness of the polyester support body is in a range of 50 μm to 300 μm, the first adhesive layer includes a modified polyolefin resin which is a copolymer of ethylene, (meth)acrylic acid ester, and acid anhydride, the second adhesive layer includes an olefin resin, and a sum of average film thicknesses of the first adhesive layer and the second adhesive layer is in a range of 0.001 times to 0.3 times the average film thickness of the polyester support body. The multilayer film is a multilayer film in which an adhesive layer having both adhesiveness to EVA and adhesiveness to a polyester support body is included, curling of the multilayer film is suppressed, and blocking is suppressed.

### CROSS-REFERENCE TO RELATED APPLICATIONS

This application is a Continuation of PCT International Application No. PCT/JP2014/057530, filed on Mar. 19, 2014, which claims priority under 35 U.S.C. Section 119(a) to Japanese Patent Application No. 2013-076755 filed on Apr. 2, 2013. Each of the above applications is hereby expressly incorporated by reference, in its entirety, into the present application.

### BACKGROUND OF THE INVENTION

1. Field of the Invention

The present invention relates to a multilayer film, a back sheet for a solar cell module, and a solar cell module. Specifically, the invention relates to a multilayer film which is used in a back sheet for a solar cell module, and in which adhesiveness of an adhesive layer to a sealing material and a polyester support body is excellent and blocking and curling are suppressed.

2. Description of the Related Art

The solar cell module generally has a structure of glass or a front sheet/a transparent filling material (sealing material)/a solar battery device/a sealing material/a back sheet (BS), which are laminated in this sequence, from a side of a light receiving surface to which sunlight is incident. Specifically, the solar battery device generally has a structure of being embedded with a resin (sealing material) such as ethylene-vinyl acetate copolymer (EVA) to which a back sheet for a solar cell module is further attached. The back sheet for the solar cell module is provided on the outermost layer of the solar cell module, and has a function of protecting the solar battery device.

In the related art, as the back sheet for the solar cell module, glass, a fluorine resin, or the like has been used, but, recently, polyester has been applied in view of cost suppression, in many cases. As the back sheet for the solar cell module using polyester, products formed by a method of using polyethylene terephthalate (PET) as a support body, and sticking another adhesive layer (polymer sheet) thereto are used.

In order to enable the solar cell module to be used for a long period of time, it is important to protect solar battery devices and sealing materials thereof from wind and rain, humidity, dust, and the like, block an inside portion of the solar cell module from the outside air, and maintain a sealed state. Therefore, high adhesiveness is required between a polyester support body of a back sheet for a solar cell module and EVA which is a sealing material. Generally, the polyester support body and EVA are configured with different components, and thus it is difficult for both to directly adhere to each other. Therefore, an adhesive layer that connects the polyester support body and EVA is provided on the polyester support body, and both are bonded through the adhesive layer.

For example, in JP2010-251679A, a multilayer film in which an adhesive layer including a maleic anhydride-modified polyolefin resin is laminated on a polyester support body is disclosed. Here, only one of these adhesive layers is provided, and it is suggested that the adhesiveness between a sealing material and a back sheet for a solar cell module is enhanced by providing the adhesive layer.

In addition, in WO2012/053475A, on the polyester support body, a multilayer film that has a first adhesive layer having a copolymer of ethylene and ester or a copolymer of ethylene and acrylic acid, as a main component, and a second adhesive layer having an olefin resin, as a main component is disclosed. Here, a total thickness of the first adhesive layer and the second adhesive layer is several tens of μm to 100 μm, and it is suggested that adhesiveness between the sealing material and the back sheet for the solar cell module is enhanced by providing the two adhesive layers.

### SUMMARY OF THE INVENTION

However, it became clear by the examination of the present inventors, that the adhesive layer used in the back sheet for the solar cell module in the related art did not have both of the adhesiveness to EVA, which is a sealing material, and the adhesiveness to the polyester support body, and the adhesiveness to the sealing material or the polyester support body was not sufficient.

In addition, if an adhesive layer having several μm to 100 μm is laminated on the polyester support body, the back sheet for the solar cell module curls and is deformed, such that the curl and the deformation are a cause of decreasing the adhesiveness of the sealing material and the polyester support body. If the back sheet for the solar cell module in which a curl is formed adheres to the sealing material, adhesion becomes inconvenient and there is a concern that the solar cell module is broken, and thus improvement has been required.

Further, it became clear by the examination of the present inventors, that in the back sheet for the solar cell module in the related art, blocking occurred when the multilayer film having the adhesive layer was wound in a roll shape. Therefore, a new improvement in which blocking does not occur, even if the multilayer film is wound in a roll shape, is required.

Therefore, in order to solve the problems in the related art, the present inventors progressed with the examination in order to provide a multilayer film in which adhesiveness to EVA is excellent and adhesiveness between the polyester support body and the adhesive layer is favorable. Further, the present inventors have proceeded with the examination in order to provide a multilayer film of which a curl is suppressed and in which blocking is suppressed.

In order to solve the problems described above, the present inventors diligently performed examinations, so as to find out that the adhesiveness to EVA and the adhesiveness to the polyester support body are enhanced if, with respect to the multilayer film having a polyester support body, a first adhesive layer laminated on at least one surface of the polyester support body, and a second adhesive layer laminated on a side opposite to the polyester support body through the first adhesive layer, binder resins included in the respective adhesive layers are specified and the ratio of average film thicknesses of the first adhesive layer and the second adhesive layer with respect to the average film thickness of the polyester support body is caused to be within a certain scope. Further, the present inventors of the invention have found that blocking and curling are suppressed in the multilayer film having the configuration described above, so as to complete the invention.

Specifically, the invention has the following configurations.

[1] A multilayer film includes a polyester support body; a first adhesive layer laminated on at least one surface of the polyester support body; and a second adhesive layer laminated on a side opposite to the polyester support body through the first adhesive layer, in which an average film thickness of the polyester support body is in a range of 50 μm to 300 μm, the first adhesive layer includes a modified polyolefin resin which is a copolymer of ethylene, (meth)acrylic acid ester, and acid anhydride, the second adhesive layer includes an olefin resin, and a sum of average film thicknesses of the first adhesive layer and the second adhesive layer is in a range of 0.001 times to 0.3 times the average film thickness of the polyester support body.

[2] The multilayer film according to [1], in which a fusion heat of modified polyolefin included in the first adhesive layer is 60 J/g or lower.

[3] The multilayer film according to [1] or [2], in which a sum of average film thicknesses of the first adhesive layer and the second adhesive layer is in a range of 0.05 μm to 15 μm.

[4] The multilayer film according to any one of [1] to [3], in which the (meth)acrylic acid ester is methyl (meth)acrylate, ethyl (meth)acrylate, or butyl (meth)acrylate.

[5] The multilayer film according to any one of [1] to [4], in which the olefin resin included in the second adhesive layer is polyethylene.

[6] The multilayer film according to any one of [1] to [4], in which the olefin resin included in the second adhesive layer is a copolymer of ethylene and at least one selected from (meth)acrylic acid ester, (meth)acrylic acid, unsaturated dicarboxylic anhydride, glycidyl (meth)acrylate and vinyl acetate.

[7] The multilayer film according to any one of [1] to [6], in which a fusion heat of the olefin resin included in the second adhesive layer is 30 J/g or greater.

[8] The multilayer film according to any one of [1] to [7], in which the first adhesive layer and the second adhesive layer are formed by coating.

[9] The multilayer film according to any one of [1] to [8], in which at least one surface of the polyester support body is subjected to a surface treatment.

[10] A back sheet for a solar cell module includes the multilayer film according to any one of [1] to [9], in which the second adhesive layer adheres to a sealing material.

[11] A solar cell module using the back sheet for a solar cell module according to [10].

According to the invention, it is possible to obtain a multilayer film in which adhesiveness to EVA is excellent and adhesiveness between the polyester support body and the adhesive layer is favorable. The multilayer film according to the invention has favorable adhesiveness to EVA which is a sealing material, and thus the inside portion of the solar cell module can be blocked from the outside air so as to maintain the sealed state.

Further, according to the invention, the multilayer film of which the curling is suppressed can be obtained. Therefore, the adhesiveness between the multilayer film and the solar cell module can be further enhanced. In addition, in the multilayer film according to the invention, blocking is suppressed, and thus handling properties when the back sheet for the solar cell module is used can be enhanced.

### BRIEF DESCRIPTION OF THE DRAWING

FIG. 1 is a diagram schematically illustrating a multilayer film according to the invention.

### DESCRIPTION OF THE PREFERRED EMBODIMENTS

Hereinafter, the invention will be described in detail. The descriptions of the constituent elements described below may be based on a representative embodiment or specific examples, but the invention is not limited to the embodiments. In addition, in this specification, the numerical scope indicated by using “to” means a scope including numerical values before and after “to” as minimum and maximum values.

(1. Multilayer Film)

The invention relates to a multilayer film having a polyester support body, a first adhesive layer, and a second adhesive layer. The first adhesive layer is laminated on at least one surface of the polyester support body, and the second adhesive layer is laminated on a side opposite to the polyester support body via the first adhesive layer. According to the invention, other layers may be provided between respective layers of the polyester support body, the first adhesive layer, and the second adhesive layer, but it is preferable that the polyester support body, the first adhesive layer, and the second adhesive layer are adjacently laminated in this sequence.

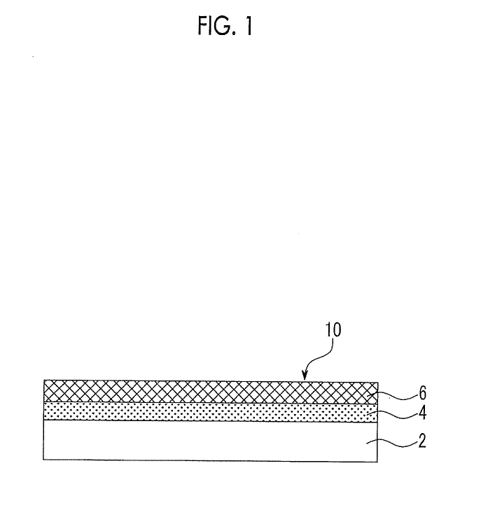

FIG. 1 is a diagram schematically illustrating a multilayer film 10 according to the invention. As illustrated in FIG. 1, the multilayer film 10 according to the invention includes a polyester support body 2, a first adhesive layer 4 laminated on the polyester support body 2, and a second adhesive layer 6 laminated on the first adhesive layer 4. In addition, the multilayer film 10 may include another layer in addition to the three layers, and it is preferable that the first adhesive layer 4 and the support body 2 are adjacent to each other, and a configuration in which the second adhesive layer 6 and an adherend such as EVA directly adhere to each other is preferable.

According to the invention, the average film thickness of the polyester support body is in the range of 50 μm to 300 μm, and the first adhesive layer includes a modified polyolefin resin which is a copolymer of ethylene, (meth)acrylic acid ester, and acid anhydride, and the second adhesive layer includes an olefin resin. In addition, the sum of the average film thicknesses of the first adhesive layer and the second adhesive layer is in the range of 0.001 times to 0.3 times the average film thickness of the polyester support body.

According to the invention, if the multilayer film has the configuration described above, it is possible to obtain the multilayer film in which adhesiveness to EVA is excellent and adhesiveness between the polyester support body and the adhesive layer is favorable. In addition, if the multilayer film has the configuration described above, the curling of the multilayer film can be suppressed.

The modified polyolefin resin which is a copolymer of ethylene, (meth)acrylic acid ester, and acid anhydride included in the first adhesive layer can enhance the adhesion to the polyester support body. In addition, the olefin resin included in the second adhesive layer can enhance the adhesion to EVA. In addition, if the total thickness of the two adhesive layers is caused to be 0.001 times to 0.3 times the average film thickness of the polyester support body, shrinkage stress occurring due to thermal shrinkage can be relieved. That is, according to the invention, if resins included in the respective adhesive layers are specified and the total thickness of the two adhesive layers is caused to be a certain scope, the adhesive strength is enhanced, and also a force causing the adhesive layer to inwardly shrink (curl) by the thermal shrinkage can be suppressed.

In addition, the shrinking (curling) force can be obtained by cutting off the multilayer film to a square of 300 mm×300 mm, disposing the multilayer film on a horizontal plane, and measuring vertical distances (mm) from a table surface at four corners to curl apexes as curl amounts. The curl amounts after the multilayer film has been left for 24 hours at 25° C. under the conditions of a relative humidity of 60% are preferably 20 mm or lower, more preferably 15 mm or lower, and still more preferably 10 mm or lower.

The total thickness of the average film thicknesses of the first adhesive layer and the second adhesive layer may be 0.001 times or more, preferably 0.003 times or more, and more preferably 0.005 times or more with respect to the average film thickness of the polyester support body. In addition, the total thickness may be 0.3 times or less, preferably 0.25 times or less, and more preferably 0.2 times or less.

In addition, the sum of the average film thicknesses of the first adhesive layer and the second adhesive layer may be 0.001 times to 0.3 times the average film thickness of the polyester support body, but the sum of the average film thicknesses of the first adhesive layer and the second adhesive layer is preferably in the range of 0.05 μm to 15 μm. The sum of the average film thicknesses of the first adhesive layer and the second adhesive layer is preferably 0.05 μm or greater, more preferably 0.1 μm or greater, still more preferably 0.5 μm or greater, and particularly preferably 1 μm or greater. In addition, the sum of the average film thicknesses of the first adhesive layer and the second adhesive layer is preferably 15 μm or less, more preferably 12 μm or less, and still more preferably 10 μm or less. In this manner, if the sum of the average film thicknesses of the first adhesive layer and the second adhesive layer is in the range described above, the blocking properties of the multilayer film are improved, and the occurrence of the curling can be suppressed.

According to the invention, the fusion heat of the modified polyolefin included in the first adhesive layer is preferably 60 J/g or lower, more preferably 50 J/g or lower, and still more preferably 40 J/g or lower. If the fusion heat of the modified polyolefin included in the first adhesive layer is in the range described above, the adhesive strength of the polyester support body including the first adhesive layer can be enhanced.

In addition, the fusion heat of the olefin resin included in the second adhesive layer is preferably 30 J/g or greater, more preferably 40 J/g or greater, and still more preferably 50 J/g or greater. In this manner, if the fusion heat of the olefin resin included in the second adhesive layer is in the range described above, the blocking occurring when the multilayer film is wound in a roll shape can be suppressed. In addition, in order to more effectively suppress the blocking while the adherence to the polyester support body is secured, the fusion heat of the olefin resin included in the second adhesive layer is preferably higher than the fusion heat of the modified polyolefin included in the first adhesive layer.

As described above, if the fusion heat of the modified polyolefin included in the first adhesive layer is in the range described above, the adhesiveness between the first adhesive layer and the polyester support body can be enhanced. It is considered that this is because, if the fusion heat of the modified polyolefin is in the range described above, an ester portion and an acid anhydride portion that constitute the modified polyolefin are easily oriented to a side of the polyester support body, and the ester portion and the acid anhydride portion can exhibit favorable adhesion to the polyester support body.

Meanwhile, a large amount of ethylene is included in EVA, and ethylene constituting the olefin resin is included in the second adhesive layer, such that adhesion between the second adhesive layer and EVA can be enhanced.

(2. Polyester Support Body)

The multilayer film according to the invention includes a polyester support body. The polyester support body is preferably a polyester film, and the polyester film is excellent in cost or mechanical strength, and thus preferably used as the support body of the multilayer film.

Polyester constituting the polyester film is preferably saturated polyester. In this manner, if saturated polyester is used, it is possible to obtain a polyester film which is excellent in view of mechanical strength compared with a film using unsaturated polyester.

Polyester has a —COO-bond or an —OCO-bond in the middle of a polymer. In addition, a terminal group of polyester is an OH group, a COOH group, or a group (OR^{X} group and COOR^{X} group (R^{X} represents an arbitrary substituent such as an alkyl group)) in which an OH group or a COOH group is protected, and is preferably linear saturated polyester synthesized from aromatic dibasic acid or an ester-forming derivative thereof and diol or an ester-forming derivative thereof. As linear saturated polyester, for example, products disclosed in JP2009-155479A or JP2010-235824A can be appropriately used.

As specific examples of linear saturated polyester, polyethylene terephthalate (PET), polyethylene isophthalate, polybutylene terephthalate, poly(1,4-cyclohexylene dimethylene terephthalate), and polyethylene-2,6-naphthalate can be included. Among them, polyethylene terephthalate or polyethylene-2,6-naphthalate is particularly preferable in view of the balance between mechanical properties and cost, and polyethylene terephthalate is more preferable.

Polyester may be a homopolymer or may be a copolymer. Further, the polyester may be a product obtained by blending a small amount of another kind of resin, for example, polyimide to polyester. In addition, as polyester, crystalline polyester that can form anisotropy at the time of melting may be used.

The average of carboxylic acid values (AV) of the polyester film is preferably 22 eq/ton or less. The average of the carboxylic acid values (AV) of the polyester film is preferably 22 eq/ton or less, more preferably 18 eq/ton or less, and still more preferably 16 eq/ton or less. In addition, the lower limit is not particularly limited, but is preferably 1 eq/ton or greater. If the carboxylic acid value (AV) of the polyester film is within the range described above, the crystallinity or heat resistance of polyester can be maintained, and the adhesion between layers of the multilayer film can be enhanced.

In addition, the carboxylic acid value (AV) of the polyester film may be adjusted by the time of solid phase polymerization described below. If the time of the solid phase polymerization is lengthened, the carboxylic acid value decreases, and if the time of the solid phase polymerization is shortened, the carboxylic acid value increases.

In addition, the polyester film may contain a terminal sealing agent. As the terminal sealing agent, a carboimide compound or a ketene imine compound can be exemplified. In the polyester film, a carboimide compound or a ketene imine compound functions as a terminal sealing agent that reacts with a terminal carboxyl group of polyester and suppresses hydrolysis of polyester. Particularly, the cyclic carbodiimide compound or the ketene imine compound is preferably used since the cyclic carbodiimide compound and the ketene imine compound can suppress hydrolysis and also can suppress the generation of volatile gas in a manufacturing process.

In view of heat resistance or viscosity, with respect to a molecular weight of polyester, a weight average molecular weight (Mw) is preferably in the range of 5,000 to 30,000, more preferably in the range of 8,000 to 26,000, and particularly preferably in the range of 12,000 to 24,000. As the weight average molecular weight of polyester, a value in terms of polymethylmethacrylate (PMMA) measured by gel permeation chromatography (GPC) using hexafluoro isopropanol as a solvent can be used.

In view of transparency, the refractive index of the polyester film is preferably in the range of 1.63 to 1.71, and more preferably in the range of 1.62 to 1.68.

In addition, the polyester film may contain another additive without departing from the gist of the invention, and an antioxidant or an ultraviolet ray inhibitor is exemplified.

Polyester can be synthesized by the well-known method. For example, polyester can be synthesized by the well-known method such as a polycondensation method, a ring opening polymerization, or the like and any one of reactions by transesterification and direct polymerization can be applied.

If polyester used in the invention is a polymer or a copolymer obtained by a condensation reaction using aromatic dibasic acid or an ester-forming derivative thereof and diol or an ester-forming derivative thereof as main components, polyester can be manufactured by performing an esterification reaction or transesterification on aromatic dibasic acid or an ester-forming derivative thereof and diol and an ester-forming derivative thereof and subsequently performing a polycondensation reaction. In addition, it is possible to control a carboxylic acid value of polyester or unique viscosity by selecting raw materials or reaction conditions. In addition, in order to effectively proceed with the esterification reaction or the transesterification, and the polycondensation reaction, it is preferable to add a polymerization catalyst at the time of these reactions.

In order to polymerize polyester, in view of suppressing the content of a carboxyl group to a predetermined range or lower, it is preferable that a Sb-based, Ge-based, or Ti-based compound is used as a catalyst, and among them, the Ti-based compound is particularly preferable. If the Ti-based compound is used, polymerization is performed by using the Ti-based compound, as a catalyst, such that a value in terms of a Ti element becomes in the range of 1 ppm to 30 ppm, and more preferably in the range of 3 ppm to 15 ppm. If the usage of the Ti-based compound is in the range described above, in terms of the Ti element, the terminal carboxyl group can be adjusted to the range as described below, and the hydrolysis resistance of the polyester support body can be maintained to be low.

Methods disclosed, for example, in JP1996-301198B (JP-H08-301198B), JP2543624B, JP3335683B, JP3717380B, JP3897756B, JP3962226B, JP3979866B, JP3996871B, JP4000867B, JP4053837B, JP4127119B, JP4134710B, JP4159154B, JP4269704B, and JP4313538B can be applied to the synthesization of polyester using the Ti-based compound.

Polyester is preferably subjected to solid phase polymerization after polymerization. Accordingly, a preferable carboxylic acid value can be achieved. As the solid phase polymerization, a continuous method (a method of filling a tower with a resin, heating and slowly circulating the resin for a predetermined period of time, and discharging the resin) may be used, or a batch method (a method of inserting a resin into a container and heating the resin for a predetermined period of time) may be used. Specifically, methods disclosed in JP2621563B, JP3121876B, JP3136774B, JP3603585B, JP3616522B, JP3617340B, JP3680523B, JP3717392B, and JP4167159B can be applied to solid layer polymerization.

The temperature of the solid phase polymerization is preferably in the range of 170° C. to 240° C., more preferably in the range of 180° C. to 230° C., and still more preferably in the range of 190° C. to 220° C. In addition, the time of the solid phase polymerization is preferably in the range of 5 hours to 100 hours, more preferably in the range of 10 hours to 75 hours, and still more preferably in the range of 15 hours to 50 hours. The solid phase polymerization is preferably performed in vacuum or under a nitrogen atmosphere.

The average film thickness of the polyester support body is in the range of 50 μm to 300 The thickness of the polyester support body may be 50 μm, preferably 75 μm or greater, and more preferably 100 μm or greater. In addition, the thickness of the polyester support body may be 300 μm or less, and preferably 250 μm or less. If the average film thickness of the polyester support body is in the range described above, the mechanical strength of the support body can become a favorable state and the cost is also advantageous. Particularly, hydrolysis resistance is deteriorated according to the increase of the thickness, and thus there is a tendency that the endurance for long term use is difficult for the polyester support body. Therefore, the thickness of the polyester support body is preferably 300 μm or less.

It is preferable that the support body according to the invention is subjected to the surface treatment before the first adhesive layer is coated as described below. As the surface treatment, a corona treatment, a flame treatment, a low pressure plasma treatment, an atmospheric pressure plasma treatment, a UV treatment, a sandblast treatment, a chromium mixed acid treatment, and the like are included. In addition, as the flame treatment, methods of performing the flame treatment while adding silane compounds disclosed in JP3893394B and JP2007-39508A can be used. Among them, in view of convenience or environmental burden, the corona treatment, the flame treatment, the atmospheric pressure plasma treatment, and the UV treatment are preferable. Cissing when the first adhesive layer is coated is prevented by subjecting the support body to the surface treatment, and the adhesiveness in a case of being exposed to a humid and hot environment is further enhanced.

(3. First Adhesive Layer)

According to the invention, the first adhesive layer includes a modified polyolefin resin which is a copolymer of ethylene, (meth)acrylic acid ester, and acid anhydride. The modified polyolefin resin is a resin which is acid-modified by acid anhydride.

As an olefin component constituting the modified polyolefin resin, ethylene is used. In addition to ethylene, propylene, butane, and the like may be mixed to the olefin component to be used.

As a carboxylic acid component, maleic anhydride, itaconic anhydride, and citraconic anhydride of acid anhydride and the like can be included. Among them, it is preferable that maleic anhydride is used. These may be used singly or two or more types thereof may be used in combination.

A formation of the acid anhydride component is not particularly limited, as long as the acid anhydride component is copolymerized in an acid-modified polyolefin resin. As a copolymerization state, for example, random copolymerization, block copolymerization, graft copolymerization (graft modification), and the like are included.

As a (meth)acrylic acid ester component, an esterification product of (meth)acrylic acid and alcohol having 1 to 30 carbon atoms is included. Among them, in view of easy obtainablility, the esterification product of (meth)acrylic acid and alcohol having 1 to 20 carbon atoms is preferable.

As specific examples of a (meth)acrylic acid ester component, methyl (meth)acrylate, ethyl (meth)acrylate, propyl (meth)acrylate, butyl (meth)acrylate, hexyl (meth)acrylate, octyl (meth)acrylate, decyl (meth)acrylate, lauryl (meth)acrylate, octyl (meth)acrylate, dodecyl (meth)acrylate, stearyl (meth)acrylate, and the like are included. Mixtures thereof may be used. Among them, in view of easy obtainablility and adhesiveness, methyl (meth)acrylate, ethyl (meth)acrylate, butyl (meth)acrylate, hexyl (meth)acrylate, and octyl (meth)acrylate are preferable, methyl (meth)acrylate, ethyl (meth)acrylate, and butyl (meth)acrylate are more preferable, and ethyl acrylate is particularly preferable. In addition, the expression “(meth)acrylate” means “acrylate or methacrylate”.

A formation of the (meth)acrylic acid ester component is not particularly limited, as long as the (meth)acrylic acid ester component is copolymerized in an acid-modified polyolefin resin. As the copolymerization state, for example, random copolymerization, block copolymerization, and graft copolymerization (graft modification) are included.

The content of acid anhydride in the modified polyolefin resin is in the range of 0.1% by mass to 10% by mass, preferably in the range of 0.5% by mass to 8% by mass, and more preferably in the range of 1% by mass to 5% by mass, and still more preferably in the range of 2% by mass to 4% by mass. If the content thereof is less than 0.1% by mass, it is difficult to form aqueous dispersion, and if the content thereof is greater than 10% by mass, weather resistance tends to decrease.

In addition, a content of the (meth)acrylic acid ester component in the modified polyolefin resin is preferably in the range of 0.1% by mass to 35% by mass, more preferably in the range of 1% by mass to 30% by mass, still more preferably in the range of 2% by mass to 28% by mass, and particularly preferably in the range of 3% by mass to 25% by mass. If the content of the (meth)acrylic acid ester component is less than 0.1% by mass, adhesiveness tends to decrease, if the content thereof is greater than 35% by mass, weather resistance or acid resistance tends to decrease.

As specific examples of the modified polyolefin resin, an ethylene-(meth)acrylic acid ester-maleic anhydride copolymer, an ethylene-propylene-(meth)acrylic acid ester-maleic anhydride copolymer, an ethylene-butene-(meth)acrylic acid ester-maleic anhydride copolymer, an ethylene-propylene-butene-(meth)acrylic acid ester-maleic anhydride copolymer, and the like are included. Among them, an ethylene-(meth)acrylic acid ester-maleic anhydride copolymer is most preferable. The formation of the copolymer may be any one of a random copolymer, a block copolymer, a graft copolymer, and the like, but in view of easy obtainablility, the random copolymer and the graft copolymer are preferable.

The fusion heat of the modified polyolefin resin as described above is preferably 60 J/g or lower, more preferably 55 J/g or lower, and still more preferably 50 J/g or lower. The modified polyolefin resin used in the present invention is amorphous (non-crystalline) at room temperature and has elasticity. Therefore, it is possible to suppress the first adhesive layer from curling, and even if a second adhesive layer described below curls, it is possible to relieve the shrinkage stress. Accordingly, it is possible to reduce a curl amount of the multilayer film.

The modified polyolefin resin is preferably in the range of 10% by mass to 90% by mass, more preferably in the range of 15% by mass to 85% by mass, and still more preferably in the range of 20% by mass to 80% by mass with respect to the total mass of the binder resin included in the first adhesive layer. If the modified polyolefin resin is contained in the range described above, it is possible to enhance the adhesiveness between the first adhesive layer and the polyester support body.

According to the invention, in view of environmental protection or in view of formation easiness of the adhesive layer, the modified polyolefin resin is preferably formed by aqueous dispersion.

In addition, for the reason of various performances or easiness of evenly forming the thickness at the time of coating, a number average particle diameter of the modified polyolefin resin in the aqueous dispersion is preferably 1 μm or less, more preferably 0.5 μm or less, still more preferably 0.2 μm or less, and particularly preferably 0.1 μm or less.

As the polyolefin resin described above, a product which is industrially obtainable may be used. As the modified polyolefin resin which is industrially obtainable, AROBASE SE-1013N, SD-1010, and SB-1010 (all manufactured by Unitika Ltd.), and the like are included. Among them, AROBASE SE-1013N or SB-1010 manufactured by Unitika Ltd. is preferably used in the invention.

In addition, if the first adhesive layer according to the invention is formed by co-extrusion, as the modified polyolefin resin which is industrially obtainable, BONDINE TX8030, HX8290, HX8140, AX8390, and LX4110, and LOTADER 3210 and 3410 (all manufactured by Arkema K.K.), and the like are included. Among them, BONDINE TX8030 or HX8290, or LOTADER 3410 manufactured by Arkema K.K. is preferably used according to the invention.

(4. Second Adhesive Layer)

According to the invention, the second adhesive layer contains an olefin resin. The olefin resin that can be used in the invention is a resin having polyolefin such as polyethylene and polypropylene, in a main chain skeleton. Among them, as the olefin resin used in the second adhesive layer, the polyethylene is preferably used.

In addition, the olefin resin used in the second adhesive layer is preferably a polyethylene resin or a copolymer of ethylene and at least one selected from the group consisting of (meth)acrylic acid ester, (meth)acrylic acid, unsaturated dicarboxylic anhydride, glycidyl (meth)acrylate, and vinyl acetate.

As specific examples of the olefin resin, for example, a polyethylene resin such as high density polyethylene (HDPE), low density polyethylene (LDPE), and linear low density polyethylene (LLDPE), an ethylene-(meth)acrylic acid copolymer, an ethylene-(meth)acrylic acid ester-(meth)acrylic acid copolymer, an ethylene-vinyl acetate copolymer, an ethylene-vinyl acetate-(meth)acrylic acid copolymer, an ethylene-propylene-(meth)acrylic acid copolymer, an ethylene-propylene-(meth)acrylic acid ester-(meth)acrylic acid copolymer, an ethylene-maleic anhydride copolymer, an ethylene-(meth)acrylic acid ester-maleic anhydride copolymer, an ethylene-butene-maleic anhydride and/or -(meth)acrylic acid copolymer, an ethylene-vinyl chloride copolymer, an ethylene-vinyl chloride copolymer, and an ethylene-(meth)acrylic acid ester copolymer are included. Among these, the ethylene-(meth)acrylic acid copolymer, the ethylene-(meth)acrylic acid ester copolymer, and the ethylene-(meth)acrylic acid ester-maleic anhydride copolymer are preferably used, and the ethylene-(meth)acrylic acid ester-maleic anhydride copolymer is particularly preferably used.

In addition, the same modified polyolefin may be included in the first adhesive layer and the second adhesive layer. In this case, the modified polyolefin resin which is a copolymer of ethylene, (meth)acrylic acid ester, and acid anhydride is included in both of the first adhesive layer and the second adhesive layer. In this case, the fusion heat of the modified polyolefin resin included in the first adhesive layer and the second adhesive layer is preferably changed.

The form and the usage mode of the olefin resin that can be used in the invention are not particularly limited, as long as the adhesive layer can be forming. For example, the olefin resin may be a water-dispersible olefin resin, or a meltable olefin resin. In addition, the olefin resin may be a crystalline olefin resin or a non-crystalline olefin resin.

As the polyolefin resin described above, products which are industrially obtainable can be used. As a modified polyolefin resin which is industrially obtainable, in the aqueous dispersion, AROBASE SE-1013N, SD-1010, SB-1010, TC-4010, and TD-4010 (all manufactured by Unitika Ltd.), HITEC 53148, 53121, and 58512 (all manufactured by Toho Chemical Industry Co., Ltd.), CHEMIPEARL S-120, S-75N, V100, and EV210H (all manufactured by Mitsui Chemicals, Inc.), and the like can be included. Among them, AROBASE SE-1013N and SD-1010 manufactured by Unitika Ltd. are preferably used in the invention.

In addition, as a resin that can be used in co-extrusion, BONDINE TX8030, HX8290, HX8140, AX8390, and LX4110, LOTADER 3210 and 3410 (all manufactured by Arkema K.K.), NUCREL N1108C and N1525 (manufactured by Du Pont-Mitsui Polychemicals), LOTRYL 17BA07N, 30BA02, and 18MA02 (manufactured by Arkema K.K.), BYNEL 4288 and 4033 (manufactured by DuPont), LUMITAK 43-1 and 22-6 (manufactured by Tosoh Corporation), and the like can be included. Among them, according to the invention, BONDINE TX8030 and LX4110, LOTADER 3210 manufactured by Arkema K.K., or the like are preferably used.

The ratio of average film thicknesses of the first adhesive layer and the second adhesive layer is preferably in the range of 1:100 to 10:1, more preferably in the range of 1:70 to 2:1, and still more preferably in the range of 1:50 to 1:1. If the ratio of the average film thicknesses of the first adhesive layer and the second adhesive layer is in the range described above, the curling of the multilayer film can be more effectively suppressed.

(5. Other Components)

In addition to the resins which are main components, the first adhesive layer and the second adhesive layer may contain various additives such as a crosslinking agent, a surfactant, a coloring pigment, an ultraviolet absorber, an ultraviolet stabilizer, a flame retardant, a plasticizer, an antistatic agent, a lubricant, and an anti-blocking agent, if necessary. Particularly, if the adhesive layer is formed by coating, at least, the crosslinking agent and the surfactant are preferably included.

[Crosslinking Agent]

As the crosslinking agent, epoxy-based, isocyanate-based, melamine-based, carbodiimide-based, or oxazoline-based crosslinking agents or the like can be included. In view of securing adhesion of a solar cell module to a sealing material after elapse of time in a humid and hot environment by enhancing aggregation force of a binder, the oxazoline-based crosslinking agent (compound having oxazoline group) is particularly preferable.

As the oxazoline-based crosslinking agent, a low molecular compound or polymer which has two or more oxazoline groups in a molecule may be used, but a polymer is more preferable since adhesiveness is favorable.

With respect to specific examples of the oxazoline-based crosslinking agent, as an oxazoline-based crosslinking agent of a low molecular compound, for example, 2-vinyl-2-oxazoline, 2-vinyl-4-methyl-2-oxazoline, 2-vinyl-5-methyl-2-oxazoline, 2-isoprophenyl-2-oxazoline, 2-isoprophenyl-4-methyl-2-oxazoline, 2-isoprophenyl-5-ethyl-2-oxazoline, 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethylene-bis-(2-oxazoline), 2,2′-octamethylene-bis-(2-oxazoline), 2,2′-ethylene-bis-(4,4′-dimethyl-2-oxazoline), 2,2′-p-phenylene-bis-(2-oxazoline), 2,2′-m-phenylene-bis-(2-oxazoline), 2,2′-m-phenylene-bis-(4,4′-dimethyl-2-oxazoline), 2,2′-(1,3-phenylene)-bis-(2-oxazoline), bis-(2-oxazolinylcyclohexane)sulfide, and bis-(2-oxazolinyl norbornane)sulfide are included. Further, (co)polymers of these compounds can be preferably used. These can be used singly or two or more types thereof may be used in combination.

The oxazoline-based crosslinking agent of the polymer necessarily uses addition polymerizable oxazoline, as a constituent component, and can be obtained by polymerizing a monomer component including a monomer copolymerizable with the addition polymerizable oxazoline.

As the addition polymerizable oxazoline, 2-vinyl-2-oxazoline, 2-vinyl-4-methyl-2-oxazoline, 2-vinyl-5-methyl-2-oxazoline, 2-isoprophenyl-2-oxazoline, 2-isoprophenyl-4-methyl-2-oxazoline, 2-isoprophenyl-5-methyl-2-oxazoline, and 2-isoprophenyl-5-ethyl-2-oxazoline are preferably included, and these can be used singly, or two or more types thereof may be used in combination. Among these, 2-isoprophenyl-2-oxazoline is preferable for easy obtainablility or favorable adhesiveness. The usage of addition polymerizable oxazoline described above is not particularly limited, but the usage is preferably 5% by mass or more, more preferably in the range of 5% by mass to 90% by mass, still more preferably in the range of 10% by mass to 60% by mass, and particularly preferably in the range of 30% by mass to 60% by mass in the monomer component.

As the monomer that is copolymerizable with the addition polymerizable oxazoline, it is preferable to be selected from products that do not react with an oxazoline group, for example, (meth)acrylate, ethyl (meth)acrylate, n-butyl (meth)acrylate, isobutyl (meth)acrylate, t-butyl (meth)acrylate, cyclohexyl (meth)acrylate, 2-ethylhexyl (meth)acrylate, methoxy polyethylene glycol (meth)acrylate, lauryl (meth)acrylate, stearyl (meth)acrylate, 2-hydroxyethyl (meth)acrylate, 2-hydroxypropyl (meth) acrylate, a monoesterified product of (meth)acrylic acid and polyethylene glycol, 2-aminoethyl (meth)acrylate and salts thereof, a caprolactone-modified material of (meth)acrylic acid, (meth)acrylic acid ester such as 2,2,6,6-tetramethylpiperidine (meth)acrylate and 1,2,2,6,6-penta-methylpiperidine (meth)acrylate; (meth)acrylic acid salt such as sodium (meth)acrylate, potassium (meth)acrylate, and ammonium (meth)acrylate; unsaturated nitrile such as acrylonitrile and methacrylonitrile; unsaturated amide such as (meth)acrylamide, N-methylol (meth)acrylamide, and N-(2-hydroxyethyl) (meth)acrylamide; vinyl ester such as vinyl acetate and vinyl propionate; vinyl ether such as methyl vinyl ether and ethyl vinyl ether; α-olefin such as ethylene and propylene; halogen-containing and α,β-unsaturated aliphatic hydrocarbon such as vinyl chloride, vinylidene chloride, and vinyl fluoride; and α,β-unsaturated aromatic hydrocarbon such as styrene, α-methyl styrene, and sodium styrene sulfonate are included, and these can be used singly or two or more types thereof may be used in combination.

As the oxazoline-based crosslinking agent, in view of excellent mixture stability of the modified polyolefin resin with the aqueous dispersion, aqueous products such as water soluble and/or water dispersible products are preferable, and water soluble products are more preferable. A polymerizing method of the oxazoline-based crosslinking agent of the polymer is not particularly limited, and the well-known methods can be employed. For example, methods of performing solution polymerization, emulsion polymerization, suspension polymerization, or bulk polymerization in an aqueous medium, and the like are included and aqueous solution, aqueous dispersion, or the like can be obtained in these methods. The oxazoline-based crosslinking agent of these polymers preferably does not substantially contain nonvolatile adjuvant in order to make adhesiveness or weather resistance favorable.

With respect to the molecular weight of the oxazoline-based crosslinking agent of the polymer, the number average molecular weight is preferably in the range of 1,000 to 80,000, more preferably in the range of 3,000 to 60,000, still more preferably in the range of 5,000 to 40,000, particularly preferably in the range of 8,000 to 30,000, and most preferably in the range of 10,000 to 20,000. If the number average molecular weight is less than 1,000, adhesiveness or weather resistance tends to decrease, and if number average molecular weight is greater than 80,000, the manufacturing of the polymer becomes difficult.

In addition, as the oxazoline-based crosslinking agent, commercially available products may be used, and, for example, aqueous dispersion-type EPOCROS K-1010E, K-1020E, K-1030E, K2010E, K2020E, and K2030E, aqueous solution-type WS500 and WS700 (all are EPOCROS series manufactured by Nippon Shokubai Co., Ltd.), and the like can be used.

The content of the crosslinking agent with respect to the sum of the solid content of the modified olefin resin is preferably in the range of 5% by mass to 75% by mass, more preferably in the range of 10% by mass to 60% by mass, and particularly preferably in the range of 15% by mass to 50% by mass. The content of the crosslinking agent is 5% by mass or more, sufficient crosslinking effect can be obtained, and thus the strength decrease of the adhesive layer or adhesion failure can be suppressed. Meanwhile, if the content thereof is 50% by mass or less, pot life of the aqueous dispersion of the modified olefin resin can be prevented from decreasing.

[Surfactant]

As the surfactant, for example, the well-known surfactants such as anionic, cationic, or nonionic surfactants can be used, and specifically, DEMOL EP (manufactured by Kao Corporation), NAROACTY CL95 (manufactured by Sanyo Chemical Industries, Ltd.), and the like are included. The surfactants may be used singly, or two or more types thereof may be used in combination.

[Coloring Pigment]

If the coloring pigment is included in the adhesive layer, power generation efficiency of a solar cell module can be increased by reflecting light that is not used in the power generation in a solar battery cell and reaches the back sheet among incident light and causing the light to return to the solar battery cell. Further, decorative properties of appearance when the solar cell module is seen from the surface side can be increased. In general, if the solar cell module is seen from the surface side, the back sheet is seen around the solar battery cell. Therefore, if a colored layer is provided on the back sheet, decorative properties are enhanced and appearance can be improved.

The coloring pigment used in the adhesive layer is not particularly limited, and can be selected according to the required reflectivity, design properties, and the like. For example, titanium oxide which is a white pigment can be preferably used.

Among the coloring pigments, at least one selected from titanium oxide, carbon black, titanium black, black composite metal oxide, a perylene-based color pigment, a cyanine-based color pigment, and quinacridone-based color pigment is preferable, titanium oxide or carbon black is more preferable, and in view of reflectivity, cost, and the like, titanium oxide is preferable.

Here, as the black composite metal oxide, composite metal oxide including at least one kind of iron, manganese, cobalt, chromium, copper, and nickel is preferable, composite metal oxide including two or more of cobalt, chromium, iron, manganese, copper, and nickel is more preferable, and at least one pigment of which a color index is selected from PBk26, PBk27, PBk28, and PBr34 is particularly preferable.

In addition, the pigment of PBk26 is composite oxide of iron, manganese, and copper, the pigment of PBk-27 is composite oxide of iron, cobalt, and chromium, PBk-28 is composite oxide of copper, chromium, and manganese, and PBr34 is composite oxide of nickel and iron.

As the cyanine-based color and the quinacridone-based color, cyanine green, cyanine blue, quinacridone red, phthalocyanine blue, phthalocyanine green, and the like are included.

As the perylene-based color pigment, perylene green, perylene black, and the like are included.

For example, if a white pigment, is used as the coloring pigment, the adhesive layer has a function of increasing power generation efficiency by irregularly reflecting light that passes through a cell among sunlight incident from the back surface of the solar cell module and causing the light to return to the cell.

The volume average particle diameter of the coloring pigment is preferably in the range of 0.03 μm to 0.9 μm, and more preferably in the range of 0.2 μm to 0.7 μm. If the volume average particle diameter of the coloring pigment is in the range described above, it is possible to suppress the decrease of the reflection efficiency of light.

The volume average particle diameter of the coloring pigment is a value (solvent: water, particle shape: non-spherical, particle refractive index: 2.7, ultrasonic treatment: none) measured by MICROTRAC MT3300EX2 manufactured by Nikkiso Co., Ltd.

(6. Method of Manufacturing Multilayer Film)

The method of manufacturing the multilayer film according to the invention includes a step of forming the first adhesive layer on at least one surface of the polyester support body and a step of forming the second adhesive layer on a side opposite to the support body through the first adhesive layer. In addition, before the step of forming the first adhesive layer on the polyester support body, it is preferable to provide a step of performing the surface treatment on a surface which is a surface of the polyester support body and on which the first adhesive layer is formed.

(6-1. Method of Forming Polyester Support Body)

The polyester support body used in the invention can be formed by the well-known method. For example, the polyester support body can be obtained by melting and extruding polyester to a film shape, cooling and solidifying the polyester with a casting drum to form an unstretched film, and stretching the unstretched film. The polyester support body is preferably a biaxially stretched film, and it is preferable that stretching is performed one or more times in a longitudinal direction at Tg° C. to (Tg+60°) C. such that the magnification (total magnification when stretching is performed 2 or more times) becomes 3 times to 6 times, and then stretching is performed in a width direction at Tg° C. to (Tg+60°) C. such that the magnification becomes 3 times to 5 times. Further, if necessary, heat treatment may be performed for 1 second to 60 seconds at 180° C. to 230° C.

(6-2. Method of Forming First Adhesive Layer)

The adhesive layer according to the invention can be formed by the well-known method such as coating, co-extrusion, or sticking. Among them, it is preferable that the adhesive layer is formed on the support body by the coating.

As the coating method, for example, the well-known coating methods such as a gravure coater or a bar coater can be used.

The coating liquid may be an aqueous liquid in which water is used as a coating solvent or may be a solvent-type liquid in which an organic solvent such as toluene or methyl ethyl ketone is used. Among them, in view of environmental burden, it is preferable that water is used as a solvent. The coating solvents may be used singly or two or more types thereof may be used in combination. As a preferable example of the coating solvent, water, water/ethyl alcohol=95/5 (mass ratio), water/methyl cellosolve=97/3 (mass ratio), and the like are included.

In addition, if the polyester support body is the biaxially stretched film, the first adhesive layer may be formed by coating the coating liquid for forming a modified polyolefin resin layer on the polyester support body after being biaxially stretched and drying the coated film or may be formed by coating the coating liquid on the polyester support body after being uniaxially stretched, drying the coated film, and stretching the film in a direction different from the first stretched direction. Further, biaxial stretching may be performed after coating liquid is coated on the polyester support body before being stretched and the coated film is dried.

(6-3. Method of Forming Second Adhesive Layer)

The second adhesive layer according to the invention can be formed by the well-known method such as coating, co-extrusion, or sticking, but a method performed by coating is preferable.

As the coating method, for example, the well-known coating methods such as a gravure coater or a bar coater can be used. With respect to the coating method or the coating liquid, the products described above can be used.

(6-4. Surface Treatment)

Before the step of forming the adhesive layer on the support body, it is preferable that a step of performing a surface treatment is provided.

As the surface treatment, a corona treatment, an ultraviolet treatment (UV treatment), a flame treatment, a low pressure plasma treatment, an atmospheric pressure plasma treatment, a sandblast treatment, and a chromium mixed acid treatment are included. In addition, as the flame treatment, methods of performing the flame treatment while adding silane compounds disclosed in JP3893394B and JP2007-39508A can be used. Among them, in view of convenience or environmental burden, the corona treatment, the flame treatment, the atmospheric pressure plasma treatment, and the ultraviolet treatment (UV treatment) are preferable.

(7. Back Sheet for Solar Cell Module)

The multilayer film according to the invention is used for various uses, but is preferably used as the back sheet for the solar cell module (protection sheet of solar cell module). The multilayer film according to the invention has excellent weather resistance and light resistance, and thus is preferably used as the back sheet for the solar cell module used in a humid and hot environment such as outdoors. In addition, since the multilayer films have high adhesion properties therebetween, even if the multilayer films are used for a long period of time, interlayer peeling or the like does not occur.

If the multilayer film according to the invention is used as the back sheet for the solar cell module, a functional layer as described below can be laminated. In order to laminate the functional layer, it is preferable to provide an easy adhesive layer therebetween.

—Weather Resistance Layer—

The multilayer film according to the invention preferably further includes a weather resistant layer containing at least one of a fluorine resin and a silicone-acrylic composite resin, on a surface which is at least one surface of the polyester support body and a surface on a side opposite to the surface on which the adhesive layer is disposed. The silicone-based composite polymer (hereinafter, also referred to as “composite polymer”) used in the invention is a polymer having a —(Si(R¹)(R²)—O)ₙ— portion and a polymer structure portion to be copolymerized with the portion.

In the “—(Si(R¹)(R²)—O)ₙ—” portion which is a polysiloxane segment in the composite polymer, R¹ and R² may be identical to each other, and represents an univalent organic group that can be covalently bonded to a Si atom.

As the “univalent organic group that can be covalently bonded to an Si atom” represented by R¹ and R², for example, a substituted or unsubstituted alkyl group (for example: methyl group or ethyl group), a substituted or unsubstituted aryl group (for example: phenyl group), a substituted or unsubstituted aralkyl group (for example: benzyl group or phenylethyl), a substituted or unsubstituted alkoxy group (for example: methoxy group, ethoxy group, or propoxy group), a substituted or unsubstituted aryloxy group (for example: phenoxy group), a substituted or unsubstituted amino group (for example: amino group or diethylamino group), a mercapto group, an amide group, a hydrogen atom, a halogen atom (for example: chlorine atom), or the like is included.

Among them, it is preferable that R¹ and R² each are independently an unsubstituted or substituted alkyl group (particularly, methyl group or ethyl group) having 1 to 4 carbon atoms, an unsubstituted or substituted phenyl group, a mercapto group, an unsubstituted amino group, or an amide group.

As specific examples of the —(Si(R¹)(R²)—O)ₙ— portion (polysiloxane portion) of the composite polymer, a hydrolysis condensate of dimethyl dimethoxy silane, a hydrolysis condensate of dimethyl dimethoxy silane/γ-methacryloxy trimethoxy silane, a hydrolysis condensate of dimethyl dimethoxy silane/vinyltrimethoxysilane, a hydrolysis condensate of dimethyl dimethoxy silane/2-hydroxyethyl trimethoxy silane, a hydrolysis condensate of dimethyl dimethoxy silane/3-glycidoxypropyltriethoxysilane, a hydrolysis condensate of dimethyl dimethoxy silane/diphenyl/dimethoxy silane/γ-methacryloxy trimethoxy silane, and the like are included.

A —(Si(R¹)(R²)—O)ₙ— portion (polysiloxane portion) of the composite polymer may be a linear structure or a branched structure. Further, a portion of the molecular chain may form a ring.

The ratio of the —(Si(R¹)(R²)—O)ₙ— portion (polysiloxane portion) of the composite polymer is preferably in the range of 15% by mass to 85% by mass with respect to the total mass of the composite polymer, and among them, the range of 20% by mass to 80% by mass is particularly preferable. If the ratio of the polysiloxane portion is less than 15% by mass, adhesiveness may be deteriorated at the time of being exposed to the humid and hot environment, and if the ratio is greater than 85% by mass, the liquid may become unstable.

In addition, with respect to the molecular weight of the —(Si(R¹)(R²)—O)ₙ— portion (polysiloxane portion) of the composite polymer, the weight average molecular weight in terms of polystyrene is in the range of about 30,000 to 1,000,000, but the range of about 50,000 to 300,000 is more preferable.

A production method of the —(Si(R¹)(R²)—O)ₙ— portion (polysiloxane portion) of the composite polymer is not particularly limited, and the well-known synthesization methods can be used. Specifically, a method of adding an acid to an aqueous solution of an alkoxy silane compound such as dimethylmethoxysilane and dimethylethoxysilane, performing condensation after hydrolysis and the like are included.

The polymer structure portion to be copolymerized with the polysiloxane portion is not particularly limited, and an acryl-based polymer, a polyurethane-based polymer, a polyester-based polymer, a rubber-based polymer, and the like can be used. Among them, in view of endurance, the acryl-based polymer is particularly preferable.

As a monomer constituting an acryl-based polymer, polymers obtained from ester of acrylic acid (for example: ethyl acrylate, butyl acrylate, hydroxyethyl acrylate, and 2-ethylhexyl acrylate), or ester of methacrylic acid (for example: methyl methacrylate, butyl methacrylate, hydroxyethyl acrylate, glycidyl methacrylate, and dimethylaminoethyl methacrylate) are included. Further, as the monomer, carboxylic acid such as acrylic acid, methacrylic acid, and itaconic acid, styrene, acrylonitrile, vinyl acetate, acrylamide, and divinyl benzene can be included.

The acryl-based polymer is a polymer obtained by polymerizing one kind or more of the monomer, and may be a homopolymer or a copolymer.

As specific examples of the acrylic polymer, a methyl methacrylate/ethyl acrylate/acrylic acid copolymer, a methyl methacrylate/ethyl acrylate/2-hydroxyethyl methacrylate/methacrylic acid copolymer, a methyl methacrylate/butyl acrylate/2-hydroxyethyl methacrylate/methacrylic acid/γ-methacryloxy trimethoxy silane copolymer, a methyl methacrylate/ethyl acrylate/glycidyl methacrylate/acrylic acid copolymer, and the like are included.

As the polyurethane-based polymer, a polyurethane-based polymer formed of polyisocyanate such as toluene diisocyanate, hexamethylene diisocyanate, and isophorone diisocyanate and polyol such as diethylene glycol, triethylene glycol, and neopentyl glycol can be preferably used. The production method of the polyurethane-based polymer is not particularly limited, and the well-known synthesization methods can be used.

As specific examples of the polyurethane-based polymer, urethane obtainable from toluene diisocyanate and diethylene glycol, urethane obtainable from toluene diisocyanate and diethylene glycol/neopentyl glycol, and urethane obtainable from hexamethylene diisocyanate and diethylene glycol are included.

As the polyester-based polymer, a polyester-based polymers formed of polycarboxylic acid such as terephthalic acid, isophthalic acid, adipic acid, and sulfoisophthalic acid and the polyol described in the section of polyurethane can be preferably used. The production method of the polyester-based polymer is not particularly limited, and the well-known methods can be used.

As specific examples of the polyester-based polymer, polyester obtainable from terephthalic acid/isophthalic acid and diethylene glycol, polyester obtainable from terephthalic acid/isophthalic acid/sulfoisophthalic acid and diethylene glycol, and polyester obtainable from adipic acid/isophthalic acid/sulfoisophthalic acid and diethylene glycol are included.

As the rubber-based polymer, a polymer formed of a diene-based monomer such as butadiene, isoprene, and chloroprene and a copolymer of these diene-based monomers and monomers such as styrene that can be copolymerized with these diene-based monomers can be preferably used. The production method of the rubber-based polymer is also not particularly limited, and the well-known synthesization methods can be used.

As specific examples of the rubber-based polymer, a rubber-based polymer formed of butadiene/styrene/methacrylic acid, a rubber-based polymer formed of butadiene/methyl methacrylate/methacrylic acid, a rubber-based polymer formed of isoprene/methyl methacrylate/methacrylic acid, a rubber-based polymer formed of chloroprene/acrylonitrile/methacrylic acid, and the like are included.

The polymers constituting the polymer structure portion to be copolymerized with the polysiloxane portion may be used singly, or two or more types thereof may be used in combination. Further, the respective polymers may be a homopolymer or a copolymer.

With respect to the molecular weight of the polymer structure portion to be copolymerized with the polysiloxane portion, the weight average molecular weight in terms of polystyrene is in the range of about 3,000 to 1,000,000, but the range of about 5,000 to 300,000 is more preferable.

A method of chemically bonding the —(Si(R¹)(R²)—O)ₙ— portion (polysiloxane portion) and the polymer structure portion to be copolymerized with the —(Si(R¹)(R²)—O)ₙ— portion is not particularly limited, and, for example, a method of respectively polymerizing the polysiloxane portion and the polymer structure portion to be copolymerized with the polysiloxane portion, and chemically bonding the respective polymers, a method of polymerizing the polysiloxane portion in advance and graft-polymerizing the polysiloxane portion, a method of polymerizing a copolymer portion and graft-polymerizing the polysiloxane portion with the copolymer portion, and the like are included. The following two methods can be easily performed and are preferable. For example, as a method of copolymerizing the acrylic polymer with the polysiloxane portion, a method of producing a polysiloxane portion obtained by copolymerizing γ-methacryloxy trimethylsilane and the like and radical-polymerizing the polysiloxane portion and an acrylic monomer is included. In addition, as a method of copolymerizing polysiloxane with an acrylic polymer portion, a method of causing hydrolysis and condensation polymerization to occur by adding an alkoxy silane compound to a water dispersion of an acrylic polymer including γ-methacryloxy trimethylsilane is included.

If the polymer structure portion to be copolymerized with the polysiloxane portion is an acryl-based polymer, the well-known methods such as emulsion polymerization and bulk polymerization can be used, but in view of easiness of synthesization and obtainability of the aqueous polymer dispersion, the emulsion polymerization is particularly preferable.

In addition, the polymerization initiator used in the graft polymerization is not particularly limited, and the well-known polymerization initiators such as potassium persulfate, ammonium persulfate, and azobisisobutyronitrile can be used.

If the silicone-based composite polymers described above are used as a binder of a weather resistant layer, it is possible to cause the adhesiveness between the weather resistant layer and the polyester support body to be particularly favorable, and it is possible to maintain the decrease of the adhesiveness to be small even if a long period of time has elapsed.

The silicone-based composite polymer is preferably caused to be a formation of aqueous polymer dispersion (so-called latex). A preferable particle diameter of the latex of the silicone-based composite polymer is in the range of about 50 nm to 500 nm, and a preferable concentration thereof is in the range of about 15% by mass to 50% by mass.

If the aqueous polymer is caused to be in the formation of latex, the silicone-based composite polymer preferably includes a hydrophilic functional group such as a carboxyl group, a sulphonic acid group, a hydroxyl group, and an amide group. If the silicone-based composite polymer according to the invention includes the carboxyl group, the carboxyl group may be neutralized by sodium, ammonium, and amine.

In addition, if the silicone-based composite polymer is used in the formation of latex, in order to increase the stability, an emulsion stabilizer such as a surfactant (for example: anionic or nonionic surfactant) and a polymer (for example: polyvinyl alcohol) may be contained. Further, if necessary, as additives of the latex, the well-known compounds such as a pH adjusting agent (for example: ammonia, triethylamine, and sodium hydrogen carbonate), a preservative (for example: 1,3,5-hexahydro-(2-hydroxyethyl)-s-triazine, and 2-(4-thiazolyl)benzimidazole), a thickening agent (for example: sodium polyacrylate and methyl cellulose), or a film forming assistant (for example: butyl carbitol acetate) may be added.

As the silicone-based composite polymer used in the invention, commercially available products are included. As specific examples of the commercially available products, CERANATE WSA1060 and 1070 (above manufactured by DIC Corporation), POLYDUREX H7620, H7630, and H7650 (above manufactured by Asahi Kasei Chemicals Corporation), and the like are included.

As a fluorine resin in which a composition for forming the weather resistant layer is contained in order to form the weather resistant layer, for example, chlorotrifluoroethylene, tetrafluoroethylene, hexafluoropropylene, vinylidene fluoride, trifluoroethylene, a chlorotrifluoroethylene-ethylene copolymer, and a tetrafluoroethylene-perfluoroalkyl vinyl ether copolymer are included. Among them, in view of solubility and weather resistance, the chlorotrifluoroethylene-vinyl ether copolymer obtained by copolymerizing a vinyl-based compound is preferable.

As the fluorine resin in which the composition for forming the weather resistant layer is contained, OBBLIGATO SW0011F (manufactured by AGC Coat-Tech Co., Ltd.), LUMIFLON LF200 (manufactured by Asahi Glass Co., Ltd.), ZEFFLE GK570 (manufactured by Daikin Industries, Ltd.), and the like are included.

In view of the weather resistance and the film strength, the content of the fluorine resin with respect to the total solid content of the composition for forming the weather resistant layer is preferably in the range of 40% by mass to 90% by mass and more preferably in the range of 50% by mass to 80% by mass.

As the silicone-acrylic composite resin in which the composition for forming the weather resistant layer is contained, CERANATE WSA1060 and WSA1070 (all manufactured by DIC Corporation), and H7620, H7630, and H7650 (all manufactured by Asahi Kasei Chemicals Corporation) are included.

In view of the weather resistance and the film strength, the content of the silicone-acrylic composite resin with respect to the total solid content of the composition for forming the weather resistant layer is preferably in the range of 40% by mass to 90% by mass and more preferably in the range of 50% by mass to 80% by mass.

In view of the weather resistance and the adhesion to a base film, the coating amount of the composition for forming the weather resistant layer is preferably in the range of 0.5 g/m² to 20 g/m² and more preferably in the range of 3 g/m² to 15 g/m².

The method of forming the composition for forming the weather resistant layer is not particularly limited, but the weather resistant layer is preferably formed by coating. As the coating method, for example, a gravure coater or a bar coater can be used.

As the coating solvent of the composition for forming the weather resistant layer, water is preferably used, and it is preferable that 60% by mass or more in the solvent included in the composition for forming the weather resistant layer is preferably water. The aqueous composition is preferable since it is unlikely to cause environmental burden, and if the ratio of the water is 60% by mass or more, the aqueous composition is advantageous in view of being explosion proof and safety. The ratio of water in the composition for forming the weather resistant layer is preferably great, in view of the environmental burden, and it is more preferable that water is included by 70% by mass or more with respect to the total solvent.

A white pigment may be added to the weather resistant layer. In addition, if the pigment is not included in the first adhesive layer and the second adhesive layer described above, it is required to add the pigment to the weather resistant layer. With respect to the kinds of the white pigment, the white pigments described in the section of the adhesive layer are preferably used.

The addition amount of the white pigment of the weather resistant layer is in the range of 0.3 g/m² to 10 g/m², and more preferably in the range of 4 g/m² to 9 g/m². If the addition amount is in the range of 0.3 g/m² to 10 g/m², favorable adhesiveness and reflectance improvement can be compatible with each other. In addition, if titanium oxide is used as the white pigment, the pigment and the ultraviolet absorber can be used together.

In addition to the coloring pigment, the weather resistant layer may contain various additives such as fine particles other than the coloring pigment, an ultraviolet absorber, an antioxidant, and a surfactant.

The film thickness of the weather resistant layer is preferably in the range of 0.5 μm to 15 μm and more preferably in the range of 3 μm to 10 μm. If the film thickness is 0.5 μm or greater, the weather resistance can be sufficiently exhibited, and if the film thickness is 15 μm or less, surface shape deterioration can be suppressed.

In addition, the weather resistant layer may be a single layer, or a configuration obtained by laminating two or more layers. The back sheet for the solar cell module according to the invention preferably has a configuration obtained by laminating two weather resistant layers.

(8. Solar Cell Module)

The solar cell module according to the invention includes the multilayer film according to the invention or the back sheet for the solar cell module according to the invention.

The solar cell module according to the invention is configured by disposing the solar battery device that converts light energy of the sunlight to electric energy between a transparent substrate to which the sunlight is incident and the aforementioned polyester film (back sheet for solar cell) according to the invention. A portion between the substrate and the polyester film can be configured by being sealed with, for example, a resin (so-called sealing agent) such as an ethylene-vinyl acetate copolymer.

The members other than the solar cell module, the solar battery cell, and the back sheet are specifically described, for example, in “Solar Light Power Generation System Constituting Material” (supervised by Sugimoto Eiichi, published by Kogyo Chosakai Publishing Co., Ltd., in 2008).

The transparent substrate may have optical transparency such that sunlight can pass therethrough, and can be appropriately selected from the base material through which light passes. In view of power generation efficiency, it is preferable that the transmissivity of light is high. For example, a glass substrate or a transparent resin such as an acrylic resin can be suitably used as the substrate.

As the solar battery device, a solar battery device based on silicon such as monocrystalline silicon, polycrystalline silicon, and amorphous silicon, a solar battery device based on a semiconductor in a III-V group or II-VI group compound such as copper-indium-gallium-selenium, copper-indium-selenium, cadmium-tellurium, or gallium-arsenic, and the like, and various kinds of the well-known solar battery devices can be applied.

### EXAMPLES

Hereinafter, with reference to examples and comparative examples, the characteristics of the invention will be described in detail. Materials, usage, ratios, processing details, processing sequences, and the like indicated in the examples below may be appropriately changed without departing from the gist of the invention. Therefore, the scope of the invention should not be strictly construed by the specific examples described below.

### Example 1

### Manufacturing of Multilayer Film

—Synthesization of Polyester Support Body—

100 kg of high purity terephthalic acid (manufactured by Mitsui Chemicals, Inc.) and 45 kg of slurry of ethylene glycol (manufactured by Nippon Shokubai Co., Ltd.) were sequentially supplied over 4 hours to an esterification reaction vessel into which about 123 kg of bis(hydroxyethyl)terephthalate was put in advance and which is maintained at a temperature of 250° C. and a pressure of 1.2×10⁵ Pa, and after the completion of the supply, the esterification reaction was performed for 1 hour. Thereafter, 123 kg of the obtained esterification reaction product was transferred to the polycondensation reaction vessel.

Subsequently, 0.3% by mass of ethyleneglycol with respect to the obtained polymer was added to the polycondensation reaction vessel to which the esterification reaction product was transferred. After stirring was performed for 5 hours after the addition, ethyleneglycol solutions of cobalt acetate and manganese acetate were added such that the value in terms of a cobalt element was 30 ppm, and the value in terms of a manganese element was 15 ppm with respect to the obtained polymer. After stirring was further performed for 5 hours, 2% by mass of ethyleneglycol solution of the titanium alkoxide compound was added such that the value in terms of a titanium element with respect to the polymer was 5 ppm. The titanium alkoxide compound (Ti content=4.44% by mass) synthesized in Example 1 disclosed in Paragraph [0083] of JP2005-340616A was used in the titanium alkoxide compound. 5 hours thereafter, 10% by mass of the ethyleneglycol solution of diethyl phosphono ethyl acetate was added such that the value became 5 ppm with respect to the obtained polymer.

Thereafter, while the low polymer was stirred at 30 rpm, the temperature of the reaction system was gradually raised from 250° C. to 285° C., and the pressure was decreased to 40 Pa. Both of the times until the temperature and the pressure reached the final temperature and the final pressure were 60 minutes. The reaction was continued for 3 hours, the reaction system was nitrogen-purged thereafter, the pressure returned to the normal pressure, and the polycondensation reaction was stopped. Also, the obtained polymer melted product was discharged to cold water in a strand shape and cut immediately, such that the pellet (diameter of about 3 mm and length of about 7 mm) of polyethylene terephthalate (PET) was obtained.

—Solid Phase Polymerization—

The obtained pellet was maintained for 30 minutes at the temperature of 220° C. in a vacuum container in which the pressure of 40 Pa was maintained, and the solid phase polymerization was performed.

—Manufacturing of Support Body—

The pellet after the solid phase polymerization was performed as described above was melted at 285° C. and cast on a metal drum, and an unstretched base having the thickness of about 2.5 mm was manufactured. Thereafter, stretching was appropriately performed in the longitudinal direction and the width direction, and the biaxially stretched polyethylene terephthalate base material (PET) having the desired thickness was obtained.

A corona discharge treatment (730 J/m²) was performed on one surface of the PET film (thickness of 188 μm) manufactured as described above. An ethylene-ethyl acrylate-maleic anhydride copolymer (manufactured by Arkema K.K., Product Name: BONDINE HX8290, hereinafter referred to as a “resin A”) and an ethylene-ethyl acrylate-maleic anhydride copolymer (manufactured by Arkema K.K., Product Name: BONDINE TX8030, hereinafter referred to as a “resin B”) were directly subjected to the co-extrusion-coating on the corona treatment surface of the PET film by a T-die film forming machine (cylinder temperature: 230° C. to 280° C. and T-die temperature: 300° C.), such that the respective thicknesses became 1 μm and 5 μm, and the resin A was on a side of the base material. As described above, the multilayer film obtained by sequentially laminating the first adhesive layer and the second adhesive layer on the biaxially stretched polyethylene terephthalate base material (PET base material) was manufactured. In addition, the thicknesses, the fusion heats, and the like of the respective layers are as described in Table 1.

### Examples 2

### Formation of First Adhesive Layer

(1) Preparation of Coating Liquid for Forming First Adhesive Layer

The coating liquid for forming the first adhesive layer was prepared by mixing the respective components in the compositions as described below.

<Composition of Coating Liquid>

| | |
|---|---|
| Polyolefin binder | 20.3 parts by mass |
| (AROBASE SB-1010 manufactured by Unitika Ltd., | |
| Concentration: 25% by mass) | |
| Oxazoline-based crosslinking agent | 4.1 parts by mass |
| (EPOCROS WS-700, manufactured by Nippon | |
| Shokubai Co., Ltd., Concentration: 25% by mass) | |
| Fluorine-based surfactant | 0.2 parts by mass |
| (Sodium = bis(3,3,4,4,5,5,6,6-nonafluoro) = | |
| 2-sulfonate oxy succinate, manufactured | |
| by Sankyo Chemical Co., Ltd., | |
| Concentration: 1% by mass) | |
| Distilled water | 75.4 parts by mass |

(2) Formation of First Adhesive Layer

The obtained coating liquid for forming the first adhesive layer was subjected to the corona discharge treatment in the condition of 730 J/m² on one surface of the biaxially stretched polyester support body described above, coating was performed by the bar coating method such that the coating weight became 1.0 g/m², drying was performed at 170° C. for 2 minutes, and the first adhesive layer having the drying thickness of about 1 μm was formed.

—Second Adhesive Layer—

(1) Preparation of Coating Liquid for Forming Second Adhesive Layer

The coating liquid for forming the second adhesive layer was prepared by mixing the respective components in the compositions as described below.

<Composition of Coating Liquid>

| | |
|---|---|
| Polyolefin binder | 78.8 parts by mass |
| (AROBASE SE-1013N, | |
| manufactured by Unitika Ltd., | |
| Concentration: 20% by mass) | |
| Oxazoline-based crosslinking agent | 16.2 parts by mass |
| (EPOCROS WS-700, Nippon Shokubai Co., Ltd., | |
| Concentration: 25% by mass) | |
| Fluorine-based surfactant | 1.8 parts by mass |
| (Sodium = bis(3,3,4,4,5,5,6,6-nonafluoro) = | |
| 2-sulfonate oxy succinate, manufactured | |
| by Sankyo Chemical Co., Ltd., | |
| Concentration: 1% by mass) | |
| Distilled water | 3.2 parts by mass |

(2) Formation of Second Adhesive Layer

The obtained coating liquid for forming the second adhesive layer was subjected to the corona discharge treatment under the condition of 730 J/m² on the first adhesive layer provided on one surface of the biaxially stretched polyester support body, coating was performed such that the coating weight became 5 g/m², drying was performed at 170° C. for 2 minutes, and the second adhesive layer having the drying thickness of about 5 μm was formed.

As described above, the multilayer film obtained by sequentially laminating the first adhesive layer and the second adhesive layer on the biaxially stretched polyester support body (PET base material) was manufactured.

### Examples 3 to 9

The multilayer films were manufactured in the same manner as in Example 1, except that the kinds of the binder constituting the second adhesive layer were changed as presented in Table 1, so as to perform evaluations.

### Comparative Example 1

The multilayer film was manufactured in the same manner as in Example 2, except that the kinds of the binder constituting the second adhesive layer were changed as presented in Table 1, so as to perform evaluations.

### Comparative Example 2

The multilayer film was manufactured in the same manner as in Example 1, except that the thicknesses of the first adhesive layer and the second adhesive layer were changed as presented in Table 1, so as to perform evaluations.

### Comparative Example 3

The multilayer film was manufactured in the same manner as in Example 1, except that the thickness of the PET was changed as presented in Table 1, so as to perform evaluations.

### Example 10 to 14, and 16

The multilayer films were manufactured in the same manner as in Example 1, except that the thicknesses of the PET, the first adhesive layer, and the second adhesive layer were changed as presented in Table 1, so as to perform evaluations.

### Example 15 and Comparative Example 4

The multilayer films were manufactured in the same manner as in Example 2, except that the thicknesses, the first adhesive layer and the second adhesive layer were changed as presented in Table 1, so as to perform evaluations.

### Comparative Examples 5 to 7

The multilayer films were manufactured in the same manner as in Example 1, except that the kinds of the binder constituting the first adhesive layer were changed as presented in Table 1, so as to perform evaluations.

### Examples 17 to 20

The multilayer films were manufactured in the same manner as in Example 1, except that the kinds of the binder constituting the first adhesive layer or the fusion heats were changed as presented in Table 1, so as to perform evaluations.

### Comparative Example 8

The multilayer film was manufactured in the same manner as in Example 1, except that only the first adhesive layer was formed and the second adhesive layer was not formed, as presented in Table 1, so as to perform evaluations.

—Evaluations—

With respect to the multilayer films obtained as described above, the following evaluations were performed. The evaluation results are presented in Table 1 below.

<Adhesiveness to PET>

The multilayer films (sample sheets) obtained in the examples and comparative examples were cut into 100 mm width×150 mm length, so as to prepare one sheet of a sample piece. The sample piece was disposed on a PEN film such that the adhesive layer side became an inner side, an EVA sheet (EVA sheet: F806 manufactured by Hangzhou First PV Material Co., Ltd) cut into 100 mm width×150 mm length was interposed therebetween, and hot pressing was performed by using a vacuum laminator (vacuum laminating machine PVL0505S manufactured Nisshinbo Holdings Inc.) so as to adhere the EVA. The adhesion condition was as described below.

Vacuum drawing at 145° C. for 5 minutes was performed by using the vacuum laminator, and pressing was performed for 10 minutes, for adhesion. A sample for an adhesion evaluation which had a portion of 100 mm from one end of the sample piece adhering as described above to which the EVA did not adhere and a remaining 50 mm portion to which the EVA sheet adhered was obtained.

The obtained sample for an adhesion evaluation was cut to a width of 15 mm, the EVA non-adhering portion on the PEN film was bent by 180 degrees and clipped in the upper clip of TENSILON (RTC-1210A manufactured by ORIENTEC), the PET film including the adhesive layer was clipped in the lower clip, and a tension test was performed at a peeling angle of 180° and a tension speed of 30 mm/min, to measure an adhesive strength. When peeling force between the PET film and the adhesive layer was not able to be measured since the peeling was performed in an interface between the EVA sheet and the adhesive layer, the peeling was caused to occur in an interface between the PET film and the adhesive layer by producing a cut on an adhesive layer with a cutter. In addition, in the evaluations described below, examples having values of 2 or higher are at a practically usable level. The results are presented in Table 1.

4: Peeling force was 6 N/mm or greater

3: Peeling force was 4 N/mm or greater and less than 6 N/mm

2: Peeling force was 1 N/mm or greater and less than 4 N/mm

1: Peeling force was less than 1 N/mm

<Adhesiveness to EVA>

The multilayer films (sample sheets) obtained in the examples and comparative examples were cut to 20 mm width×150 mm length, so as to prepare one sheet of sample piece. The sample piece was disposed on glass such that the adhesive layer side became an inner side, an EVA sheet (EVA sheet: F806 manufactured by Hangzhou First PV Material Co., Ltd.) cut into 20 mm width×100 mm length was interposed therebetween, and hot pressing was performed by using the vacuum laminator (vacuum laminating machine PVL0505S manufactured Nisshinbo Holdings Inc.) so as to adhere the EVA. The adhesion condition was as described below.

The vacuum drawing at 145° C. for 5 minutes was performed by using the vacuum laminator, and pressing was performed for 10 minutes, for adhesion. A sample for an adhesion evaluation which had a portion of 20 mm from one end of the sample piece adhering as described above to which the EVA did not adhere and a remaining 100 mm portion to which the EVA sheet adhered was obtained. The EVA non-adhering portions of the obtained sample for an adhesion evaluation were clipped in the upper and lower clips of TENSILON (RTC-1210A manufactured by ORIENTEC), and a tension test was performed at a peeling angle of 180° and a tension speed of 30 mm/min, to measure an adhesive strength. In addition, in the evaluations described below, examples having values of 2 or higher are at a practically usable level. The results are presented in Table 1.

4: Peeling force was 8 N/mm or greater

3: Peeling force was 5 N/mm or greater and less than 8 N/mm

2: Peeling force was 1 N/mm or greater and less than 5 N/mm

1: Peeling force was less than 1 N/mm

<Blocking Evaluation>

The multilayer films obtained in the examples and comparative examples were wound around paper pipes having a diameter of 3 inches and a width of 350 mm, by 100 m, and so as to manufacture evaluation samples. The evaluation samples were kept for 1 week in an atmosphere of 40° C., and circumstances when feeding was performed again were evaluated based on the following standards. In addition, in the evaluations described below, examples having values of 2 or higher are at a practically usable level. The results are presented in Table 1.

4: Feeding was able be performed without resistance.

3: Feeding was able be performed, but blocking traces slightly remained only in a border portion.

2: Feeding was able be performed, but blocking traces slightly remained inside of a sheet, in addition to a border portion.

1: Blocking occurs, and feeding was not able to be performed.

<Curl Amount Measurement>

The multilayer films obtained in the examples and comparative examples were cut off into squares of 300 mm×300 mm and disposed on a horizontal table, and vertical distances (mm) from the table surface at four corners to curl apexes were measured. An average value of the obtained respective distances at the four portions was calculated as a curl amount (mm). In the evaluations, examples having values of 2 or higher are at a practically usable level. The results are presented in Table 1.

3: A curl amount was less than 2 mm

2: A curl amount was 2 mm or greater and less than 4 mm

1: A curl amount was 4 mm or greater

In addition, the kinds of the resins used in the examples and the comparative examples were as follows.

A: BONDINE HX8290 (manufactured by Arkema K.K.)

B: BONDINE TX8030 (manufactured by Arkema K.K.)

C: AROBASE SB-1010 (manufactured by Unitika Ltd.)

D: AROBASE SE-1013N (manufactured by Unitika Ltd.)

E: HI-ZEX 1700J (manufactured by Prime Polymer Co., Ltd.)

F: BYNEL 40E529 (manufactured by DuPont)

G: SUMIKATHENE L405 (manufactured by Sumitomo Chemical Co., Ltd.)

H: LOTADER 3210 (manufactured by Arkema K.K.)

NUCREL N1108C (manufactured by Du Pont-Mitsui Polychemicals)

J: LOTRYL 17BA07N (manufactured by Arkema K.K.)

K: BONDINE HX8140 (manufactured by Arkema K.K.)

L: JONCRYL PDX-7341 (manufactured by BASF SE)

M: HITEC S3121 (manufactured by Toho Chemical Industry Co., Ltd.)

N: BYNEL 4288 (manufactured by DuPont)

O: LOTADER 3410 (manufactured by Arkema K.K.)

In addition, the components of the resins used in the respective adhesive layers are as follows.

E: Ethylene

AA: Acrylic acid

EA: Ethyl acrylate

BA: Butyl acrylate

MAH: Maleic anhydride

HDPE: High density polyethylene

LDPE: Low density polyethylene

TABLE 1

| | Multilayer film | | | | | | | | | | | | | |
|---|---|---|---|---|---|---|---|---|---|---|---|---|---|---|
| | | | | | Se- | | | | | Film | Evaluation | | | |
| | First | | | | cond | | | | | Thick- | Ad- | Ad- | | |
| | ad- | | Fu- | | ad- | | Fu- | | PET | ness | he- | he- | | |
| | hesive | Name | sion | Thick- | hesive | Name | sion | Thick- | Thick- | S1 + | sion | sion | | |
| | layer | of | heat | ness | layer | of | heat | ness | ness | S2)/ | to | to | Block- | |
| | (S1) | resin | (J/g) | (μm) | (S2) | resin | (J/g) | (μm) | (μm) | PET | PET | EVA | king | Curl |
| Exam- | E-EA- | A | 27 | 1 | E-EA- | B | 52 | 5 | 188 | 0.03 | 4 | 4 | 3 | 3 |
| ple 1 | MAH | | | | MAH | | | | | | | | | |
| Exam- | E-EA- | C | 29 | 1 | E-EA- | D | 48 | 5 | 188 | 0.03 | 4 | 4 | 3 | 3 |
| ple 2 | MAH | | | | MAH | | | | | | | | | |
| Exam- | E-EA- | A | 27 | 1 | HDPE | E | 197 | 5 | 188 | 0.03 | 4 | 2 | 4 | 2 |
| ple 3 | MAH | | | | | | | | | | | | | |
| Exam- | E-EA- | A | 27 | 1 | E-MAH | F | 128 | 5 | 188 | 0.03 | 4 | 3 | 4 | 2 |
| ple 4 | MAH | | | | | | | | | | | | | |
| Exam- | E-EA- | A | 27 | 1 | LDPE | G | 89 | 5 | 188 | 0.03 | 4 | 3 | 3 | 3 |
| ple 5 | MAH | | | | | | | | | | | | | |
| Exam- | E-EA- | A | 27 | 1 | E-BA- | H | 72 | 5 | 188 | 0.03 | 4 | 4 | 3 | 3 |
| ple 6 | MAH | | | | MAH | | | | | | | | | |
| Exam- | E-EA- | A | 27 | 1 | E-AA | I | 63 | 5 | 188 | 0.03 | 4 | 3 | 3 | 3 |
| ple 7 | MAH | | | | | | | | | | | | | |
| Exam- | E-EA- | A | 27 | 1 | E-BA | J | 35 | 5 | 188 | 0.03 | 4 | 4 | 3 | 3 |
| ple 8 | MAH | | | | | | | | | | | | | |
| Exam- | E-EA- | A | 27 | 1 | E-EA- | K | 10 | 5 | 188 | 0.03 | 4 | 4 | 2 | 3 |
| ple 9 | MAH | | | | MAH | | | | | | | | | |
| Com- | E-EA- | C | 29 | 1 | Acryl | L | — | 5 | 188 | 0.03 | 4 | 1 | 4 | 3 |
| parative | MAH | | | | | | | | | | | | | |
| Exam- | | | | | | | | | | | | | | |
| ple 1 | | | | | | | | | | | | | | |
| Com- | E-EA- | A | 27 | 25 | E-EA- | B | 52 | 75 | 188 | 0.53 | 4 | 4 | 1 | 1 |
| parative | MAH | | | | MAH | | | | | | | | | |
| Exam- | | | | | | | | | | | | | | |
| ple 2 | | | | | | | | | | | | | | |
| Com- | E-EA- | A | 27 | 1 | E-EA- | B | 52 | 5 | 25 | 0.24 | 4 | 4 | 2 | 1 |
| parative | MAH | | | | MAH | | | | | | | | | |
| Exam- | | | | | | | | | | | | | | |
| ple 3 | | | | | | | | | | | | | | |
| Exam- | E-EA- | A | 27 | 1 | E-EA- | B | 52 | 5 | 250 | 0.02 | 4 | 4 | 3 | 3 |
| ple 10 | MAH | | | | MAH | | | | | | | | | |
| Exam- | E-EA- | A | 27 | 1 | E-EA- | B | 52 | 5 | 125 | 0.05 | 4 | 4 | 3 | 3 |
| ple 11 | MAH | | | | MAH | | | | | | | | | |
| Exam- | E-EA- | A | 27 | 20 | E-EA- | B | 52 | 70 | 300 | 0.30 | 4 | 4 | 2 | 3 |
| ple 12 | MAH | | | | MAH | | | | | | | | | |
| Exam- | E-EA- | A | 27 | 5 | E-EA- | B | 52 | 10 | 50 | 0.30 | 4 | 4 | 3 | 2 |
| ple 13 | MAH | | | | MAH | | | | | | | | | |
| Exam- | E-EA- | A | 27 | 5 | E-EA- | B | 52 | 10 | 188 | 0.08 | 4 | 4 | 3 | 3 |
| ple 14 | MAH | | | | MAH | | | | | | | | | |
| Exam- | E-EA- | C | 29 | 0.1 | E-EA- | D | 48 | 1 | 188 | 0.006 | 4 | 4 | 3 | 3 |
| ple 15 | MAH | | | | MAH | | | | | | | | | |
| Exam- | E-EA- | A | 27 | 0.1 | E-EA- | B | 52 | 0.1 | 188 | 0.001 | 4 | 3 | 4 | 3 |
| ple 16 | MAH | | | | MAH | | | | | | | | | |
| Com- | E-EA- | C | 29 | 0.01 | E-EA- | D | 48 | 0.01 | 188 | 0.0001 | 3 | 1 | 4 | 3 |
| parative | MAH | | | | MAH | | | | | | | | | |
| Exam- | | | | | | | | | | | | | | |
| ple 4 | | | | | | | | | | | | | | |
| Com- | E-AA | M | — | 1 | E-EA- | B | 52 | 5 | 188 | 0.03 | 1 | 4 | 3 | 3 |
| parative | | | | | MAH | | | | | | | | | |
| Exam- | | | | | | | | | | | | | | |
| ple 5 | | | | | | | | | | | | | | |
| Com- | E-BA | J | — | 1 | E-EA- | B | 52 | 5 | 188 | 0.03 | 1 | 4 | 3 | 3 |
| parative | | | | | MAH | | | | | | | | | |
| Exam- | | | | | | | | | | | | | | |
| ple 6 | | | | | | | | | | | | | | |
| Com- | E- | N | — | 1 | E-EA- | B | 52 | 5 | 188 | 0.03 | 1 | 4 | 3 | 3 |
| parative | MAH | | | | MAH | | | | | | | | | |
| Exam- | | | | | | | | | | | | | | |
| ple 7 | | | | | | | | | | | | | | |
| Exam- | E-BA- | H | 72 | 1 | E-EA- | B | 52 | 5 | 188 | 0.03 | 2 | 4 | 3 | 3 |
| ple 17 | MAH | | | | MAH | | | | | | | | | |
| Exam- | E-EA- | B | 52 | 1 | E-EA- | B | 52 | 5 | 188 | 0.03 | 3 | 4 | 3 | 3 |
| ple 18 | MAH | | | | MAH | | | | | | | | | |
| Exam- | E-BA- | O | 29 | 1 | E-EA- | B | 52 | 5 | 188 | 0.03 | 4 | 4 | 3 | 3 |
| ple 19 | MAH | | | | MAH | | | | | | | | | |
| Exam- | E-EA- | K | 10 | 1 | E-EA- | B | 52 | 5 | 188 | 0.03 | 4 | 4 | 3 | 3 |
| ple 20 | MAH | | | | MAH | | | | | | | | | |
| Com- | E-EA- | A | 27 | 10 | — | — | — | — | 188 | 0.05 | 4 | 4 | 1 | 3 |
| parative | MAH | | | | | | | | | | | | | |
| Exam- | | | | | | | | | | | | | | |
| ple 8 | | | | | | | | | | | | | | |

As understood in Table 1, in Examples 1 to 20, the adhesiveness to the polyester support body and the adhesiveness to EVA were compatible with each other. Further, the generation of the blocking was suppressed, and also the curl amount was suppressed.

In addition, from Examples 14 to 16, it was understood that the thickness of the adhesive layer was thin, and thus the generation of the blocking was suppressed. Further, from Examples 17 to 20, it was understood that as the fusion heat of the first adhesive layer became lower, the adhesion to the polyester support body became more excellent.

Meanwhile, in Comparative Example 1, the olefin resin was not included in the second adhesive layer, and thus adhesiveness to EVA was not obtained. In addition, in Comparative Example 2, the sum of the average film thicknesses of the first adhesive layer and the second adhesive layer was more than 0.3 times the average film thickness of the polyester support body, and in Comparative Example 3, the average film thickness of the polyester support body was lower than 50 μm. Therefore, it was understood that the generation of the blocking was great, and the curl amount was increased.

In addition, in Comparative Example 4, the sum of the average film thicknesses of the first adhesive layer and the second adhesive layer was lower than 0.001 times the average film thickness of the polyester support body, and thus the adhesiveness to EVA was not obtained. Meanwhile, in Comparative Examples 5 to 7, the modified polyolefin resin which is a copolymer of ethylene, (meth)acrylic acid ester, and acid anhydride was included in the first adhesive layer, and thus the adhesiveness to the polyester support body was not obtained.

In addition, in Comparative Example 8, the second adhesive layer was not provided, and thus blocking was generated.

### Examples 101 to 120

Further, according to the invention, the weather resistant layer was formed in the multilayer film, and the back sheet for the solar cell module was manufactured. In addition, the solar cell module including the back sheet for the solar cell module was manufactured, and the evaluation was performed.

<Formation of Weather Resistant Layer>

A first layer of the weather resistant layer described below and a second layer of the weather resistant layer described below were formed in this sequence, on a side opposite to the surface on which the adhesive layer of the polyester support body was coated.

—Preparation of Coating Liquid for Forming First Layer of Weather Resistant Layer—

Respective components indicated in the compositions of the coating liquid for forming the first layer of the weather resistant layer as described below were mixed, and the coating liquid for forming the first layer of the weather resistant layer was prepared.

(Composition of Coating Liquid for Forming First Layer of Weather Resistant Layer)

| | |
|---|---|
| Acryl/silicone-based binder (silicone-based resin) | 188 parts by mass |
| [CERANATE WSA-1070, manufactured by | |
| DIC Corporation, Solid content: 40%] | |
| Aqueous oxazoline compound | 58 parts by mass |
| [EPOCROS WS-700, manufactured by | |
| Nippon Shokubai Co., Ltd., Solid content: | |
| 25% by mass] | |
| Fluorine-based surfactant | 9.4 parts by mass |
| (Sodium = bis(3,3,4,4,5,5,6,6-nonafluoro) = | |
| 2-sulfonate oxy succinate, manufactured | |
| by FUJIFILM Finechemicals Co., Ltd., | |
| Density: 1% by mass) | |
| Aforementioned white inorganic | 254 parts by mass |
| fine particle dispersion 1 | |
| Secondary ammonium phosphate | 6.2 parts by mass |
| [Secondary ammonium phosphate for | |
| food additive, manufactured by Nippon | |
| Chemical Industrial Co., Ltd., | |
| 35% aqueous solution] | |

—Formation of First Layer of Weather Resistant Layer—

A surface opposite to the surface which is coated with the white colored layer of the white PET film was transported at a transport speed of 80 m/min, and a corona discharge treatment was performed in the condition of 730 J/m². Thereafter, the surface subjected to the corona discharge treatment was coated with the coating liquid for forming the first layer of the weather resistant layer such that the amount of the titanium oxide was 10.5 g/m² in the coating amount, drying was performed for two minutes at 170° C., and the first layer of the weather resistant layer was formed.

—Preparation of Coating Liquid for Second Layer of Weather Resistant Layer—

Respective components indicated in the composition of the coating liquid for forming the second layer of the weather resistant layer as described below were mixed, and the coating liquid for forming the second layer of the weather resistant layer was prepared.

(Composition of Coating Liquid for Forming Second Layer of Weather Resistant Layer)

| | |
|---|---|
| Fluorine-based binder | 43 parts by mass |
| [OBBLIGATO SW0011F, manufactured by AGC | |
| Coat-Tech Co., Ltd., Solid content: | |
| 36% diluted with water] | |
| Aqueous oxazoline compound | 12 parts by mass |
| [EPOCROS WS-700, manufactured by Nippon | |
| Shokubai Co., Ltd., Solid content: | |
| 25% by mass] | |
| Nonionic surfactant | 1.5 parts by mass |
| [NAROACTY CL95, manufactured by Sanyo | |
| Chemical Industries, Ltd., Solid | |
| content: 1% aqueous solution] | |
| Secondary ammonium phosphate | 1.3 parts by mass |
| [Secondary ammonium phosphate for | |
| food additive, manufactured by Nippon | |
| Chemical Industrial Co., Ltd., | |
| 35% aqueous solution] | |
| Lubricant | 25.7 parts by mass |
| [CHEMIPEARL W950, manufactured by Mitsui | |
| Chemicals, Inc., Solid content: 5% | |
| diluted with water] | |
| Mat agent | 5 parts by mass |
| [SNOWTEX UP, manufactured by Nissan | |
| Chemical Industries, Ltd., Solid content | |
| 2% diluted with water] | |
| Silane coupling agent | 5 parts by mass |
| [TSL8340, manufactured by Momentive | |
| Performance Materials Inc., Solid content | |
| 2% hydrolyzed solution] | |
| Distilled water | 114 parts by mass |

—Formation of Second Layer of Weather Resistant Layer—

The first layer of the weather resistant layer was coated with the obtained coating liquid for forming the second layer of the weather resistant layer such that the amount of the fluorine resin was 1.5 g/m² by the coating amount, drying was performed for 2 minutes at 170° C., and the second layer of the weather resistant layer having the drying thickness of 1.5 μm was formed.

In this manner, the first adhesive layer and the second adhesive layer were provided on one surface of the polyester support body, and the back sheet for the solar cell module having the first layer of the weather resistant layer and the second layer of the weather resistant layer on the surface opposite to the polyester support body was created. With respect to Examples 1 to 20, the back sheets for the solar cell modules provided in the weather resistant layers were set respectively to Examples 101 to 120.

The back sheets for the solar cell modules of Examples 101 to 120 were evaluated so as to exhibit favorable performances.

### Examples 201 to 220

### Manufacturing and Evaluation of Solar Cell Module

Hardened glass having a thickness of 3 mm, an EVA sheet (EVA sheet manufactured by Hangzhou First PV Material Co., Ltd.: F806), a crystalline solar battery cell, an EVA sheet (EVA sheet F806: manufactured by Hangzhou First PV Material Co., Ltd.), and a back sheet for the solar cell module in each example were overlapped in this sequence, and hot pressing was performed by a vacuum laminator (vacuum laminating machine manufactured Nisshinbo Holdings Inc.) so as to adhere the EVA and the respective members. At this point, the back sheet for the solar cell module of each example was disposed such that the second adhesive layer came into contact with the EVA. The second adhesive layer and the EVA were pressed for 10 minutes for adhesion, after vacuum drawing at 150° C. for 3 minutes was performed by using the vacuum laminator.

In this manner, a crystalline solar cell module was manufactured. A power generation operation was performed by using the obtained solar cell module, favorable power generation performance as a solar cell was exhibited, and a stable operation was performed over a long period of time.

According to the invention, a multilayer film in which adhesiveness to the EVA is excellent and adhesiveness between the polyester support body and the adhesive layer is favorable can be obtained. According to the invention, the multilayer film of which curling was suppressed can be obtained. Therefore, the multilayer film according to the invention can be effectively used as the back sheet for the solar cell module, and thus has high industrial applicability.

### EXPLANATION OF REFERENCES

2: polyester support body
4: first adhesive layer
6: second adhesive layer
10: multilayer film

What is claimed is:

1. A multilayer film comprising:
a polyester support body;
a first adhesive layer laminated on at least one surface of the polyester support body; and
a second adhesive layer laminated on a side opposite to the polyester support body through the first adhesive layer,
wherein an average film thickness of the polyester support body is in a range of 50 μm to 300 μm,
the first adhesive layer includes a modified polyolefin resin which is a copolymer of ethylene, (meth)acrylic acid ester, and acid anhydride,
the second adhesive layer includes an olefin resin, and
a sum of average film thicknesses of the first adhesive layer and the second adhesive layer is in a range of 0.001 times to 0.3 times the average film thickness of the polyester support body.

2. The multilayer film according to claim 1,
wherein a fusion heat of modified polyolefin included in the first adhesive layer is 60 J/g or lower.

3. The multilayer film according to claim 1,
wherein a sum of average film thicknesses of the first adhesive layer and the second adhesive layer is in a range of 0.05 μm to 15 μm.

4. The multilayer film according to claim 1,
wherein the (meth)acrylic acid ester is methyl (meth)acrylate, ethyl (meth)acrylate, or butyl (meth)acrylate.

5. The multilayer film according to claim 1,
wherein the olefin resin included in the second adhesive layer is polyethylene.

6. The multilayer film according to claim 1,
wherein the olefin resin included in the second adhesive layer is a copolymer of ethylene and at least one selected from (meth)acrylic acid ester, (meth)acrylic acid, unsaturated dicarboxylic anhydride, glycidyl (meth)acrylate and vinyl acetate.

7. The multilayer film according to claim 1,
wherein a fusion heat of the olefin resin included in the second adhesive layer is 30 J/g or greater.

8. The multilayer film according to claim 1,
wherein the first adhesive layer and the second adhesive layer are formed by coating.

9. The multilayer film according to claim 1,
wherein at least one surface of the polyester support body is subjected to a surface treatment.

10. A back sheet for a solar cell module, comprising:
the multilayer film according to claim 1,
wherein the second adhesive layer adheres to a sealing material.

11. A solar cell module using the back sheet for a solar cell module according to claim 10.
